(19) United States
(12) Patent Application Publication
(10) Pub. No.: US 2003/0003694 A1
(43) Pub. Date: Jan. 2, 2003

(54) Method for forming silicon films with trace impurities

(76) Inventor: Apostolos Voutsas, Vancouver, WA (US)

Correspondence Address: David C. Ripma, Patent Counsel, Sharp Laboratories of America, Inc., 5750 NW Pacific Rim Boulevard, Camas, WA, 98607, US

(21) Appl. No.: 09/893,866

(22) Filed: Jun. 28, 2001

(51) Int. Cl. H01L 21/20; H01L 21/36

(52) U.S. Cl. 438/478

(57) ABSTRACT

A method is provided for forming silicon films with a controlled amount of trace impurities. The method comprises: forming a target including silicon and a first concentration of a first impurity; supplying a substrate; and, sputter depositing a film of silicon on the substrate including a second concentration of the first impurity. The first impurity in the target can be a transistion metal, phosphorous, or germanium. When the first impurity is Ni, the first concentration of nickel in the target is in the range of 0.01 to 0.5 percentage by atomic weight (at %). Preferably the range is 0.05 to 0.2 at %. Then, the second concentration of Ni in the deposited silicon film is in the range of 0.01 to 0.5 at %.

### BACKGROUND OF THE INVENTION

1. Field of the Invention

This invention generally relates to liquid crystal display (LCD) and integrated circuit (IC) fabrication and, more particularly, to a method for forming a crystallized silicon film with trace impurities for use in the polycrystalline thin film transistors (TFTs) of Active Matrix (AM) LCDs.

2. Description of the Related Art

Silicon films enriched with a small amount of nickel (Ni) can be annealed more quickly by solid-phase-crystallization than pure-Si films. This is due to the catalytic action (as far as crystallization), afforded by the formation of a silicide between the silicon (Si) and Ni atoms. To introduce the Ni impurity into the silicon films, several approaches have been implemented. In one conventional approach, a silicon film is initially deposited by conventional means and, after deposition, is coated with a Ni-rich liquid solution. After coating, the film with the Ni-rich coating is heated at temperatures suitable for the formation of Si—Ni silicide. Then, the remaining solution is removed from the surface, the surface is cleaned, and the thin Si-film is crystallized by an appropriate annealing step, such as furnace annealing or rapid thermal annealing (RTP).

In another conventional approach, a very thin layer of Ni is evaporated on a Si film that is initially deposited by conventional methods. Subsequent steps are similar to the above-mentioned case. In yet another approach, Ni is implanted into a silicon film that is initially deposited by conventional means. After implantation, the film is initially annealed at low temperature to form silicide, followed by higher temperature anneal to completely crystallize the silicon layer.

It is obvious that the first two conventional approaches mentioned above require additional steps to introduce Ni into the silicon film, and to subsequently remove the excess Ni from the surface of the silicon layer. In a large-scale factory implantation, the process costs of these “extra” steps can be quite high. Furthermore, the process typically introduces damage into the silicon film, making the film more difficult to crystallize. The opposite effect from what is desired.

It would be advantageous if impurities, such as Ni, could be introduced into a silicon film with a fewer number of process steps. It would be advantageous if the reduced-step impurity introduction process could be performed at low temperatures.

It would be desirable to develop an easier and faster silicide process that reduces the risk of damage to the silicon film being crystallized.

### SUMMARY OF THE INVENTION

The present invention permits the introduction of controlled amounts of Ni, or other transistion metal, during the deposition of a silicon film. This invention uses a sputtering process to deposit the silicon film from a target that is partially doped with Ni atoms. In this manner, Ni-doping occurs simultaneously with the deposition of the Si film, and no extra steps are required to add the Ni impurities into the silicon film.

Accordingly, a method is provided for forming silicon films with a controlled amount of trace impurities. The method comprises: forming a target including silicon and a first concentration of a first impurity; supplying a substrate; and, sputter depositing a film of silicon on the substrate including a second concentration of the first impurity.

Forming a target including silicon and a first concentration of a first impurity includes using a first impurity selected from the group including transistion metals, phosphorous, and germanium. When the first impurity is Ni, the first concentration of nickel in the target is in the range of 0.01 to 0.5 percentage by atomic weight (at %). Preferably the range is 0.05 to 0.2 at %. Then, the second concentration of Ni in the depositing a silicon film is in the range of 0.01 to 0.5 at %.

When the first impurity is germanium, the first concentration of germanium in the target is in the range of 5 to 30 at %, and the second concentration of germanium in the deposited silicon film is in the range of 5 to 30 at %.

Phosphorous can be added as an additional impurity, with either nickel or germanium. The concentration of phosphorous in the target is less than 5×e¹⁷ atomic weight per cubic centimeter (at/cm³). As a result, the concentration of phosphorous in the deposited silicon film is sufficient to create a Vth shift.

Following the formation of the silicon film with the second concentration of a transistion metal, the method comprises: annealing the silicon film including the first impurity to form a silicide; and, annealing the silicon film with the silicide to crystallize the silicon film.

Additional details of the above-described method, and alternate methods of the present invention are presented below.

### BRIEF DESCRIPTION OF THE DRAWING

FIG. 1 is a schematic block diagram, partial cross-section of a DC sputtering chamber, or reactor (prior art).

FIG. 2 is a comparison illustrating the number of steps saved in the present invention process of fabricating a silicon film with a controlled amount of impurities.

FIG. 3 is a flowchart illustrating the present invention method for forming silicon films with a controlled amount of trace impurities in the fabrication of LCDs.

FIG. 4 is a flowchart illustrating the present invention method for depositing silicon films with trace impurities in the fabrication of LCDs.

### DETAILED DESCRIPTION OF THE PREFERRED EMBODIMENTS

As noted in U.S. Pat. No. 6,149,784 (Su et al.), sputtering, or physical vapor deposition (PVD), is the favored technique for depositing materials, particularly metals and metal-based materials, in the fabrication of semiconductor integrated circuits. Sputtering has a high deposition rate and, in most cases, uses relatively simple and inexpensive fabrication equipment and relatively inexpensive material precursors, targets in the case of PVD. The usual type of sputtering used in commercial applications is DC magnetron sputtering, which is limited to the sputtering of metallic target. Sputtering is widely used for the deposition of aluminum (Al) to form metallization levels in semiconductor liquid crystal displays. More recently, copper deposition by PVD has been developed. However, sputtering is applicable to a wider range of materials useful in the fabrication of semiconductor integrated circuits. Reactive sputtering is well known in which a target of a metal, such as titanium or tantalum, is sputtered in the presence of a reactive gas in the plasma, most typically nitrogen. Thereby, the sputtered metal atoms react with the reactive gas to deposit a metal compound on the wafer, most particularly, a metal nitride, such as titanium nitride using a titanium target in a nitrogen ambient or tantalum nitride using a tantalum target in a nitrogen ambient.

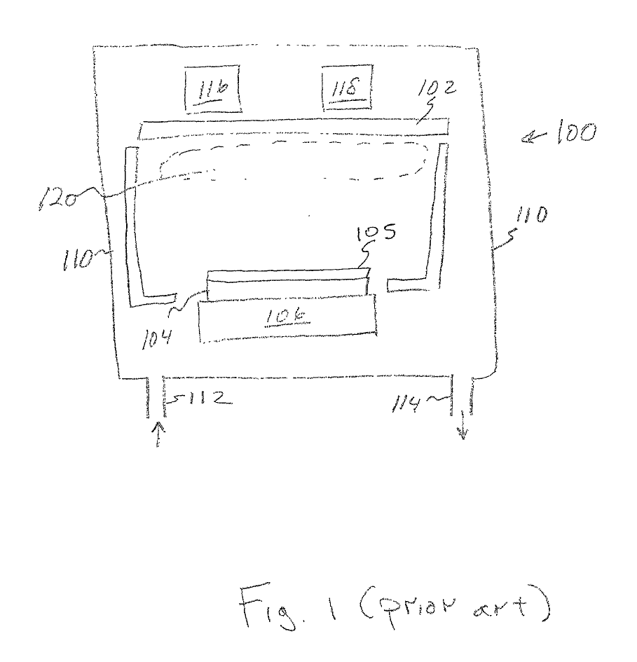

FIG. 1 is a schematic block diagram, partial cross-section of a DC sputtering chamber, or reactor 100 (prior art). The reactor 100 is vacuum-sealed and has a target or cathode 102. Typically, the target 102 is a metal, but semiconductor and insulator materials can also be used. The target material is sputtered onto a substrate 104 to form a film 105. The substrate 104 is held on a heater pedestal electrode 106 or an electrostatic chuck. An anode 108 acts as a dark space shield to protect the chamber wall 110 from the sputtered material and provides a return path or collection surface for the electrons emitted from the cathode target 102. A controllable pulsed DC power supply (not shown) negatively biases the target 102 with respect to the anode 108. Conventionally, the pedestal 106 and substrate 104 are left electrically floating, but a DC self-bias can be used to attract positively charged ions from the plasma.

Gas enters the reactor 100 from an inlet port 112, and gas exits through an exhaust port 114. The sputtering gas is often argon. The gas flow is regulated to maintain interior of the reactor 100 at a low pressure. The conventional pressure of the argon working gas is typically maintained at between about 1 and 1000 mTorr. When the argon is admitted into the reactor 100, the DC voltage applied between the target 102 and the anode 108 ignites the argon into a plasma, and the positively charged argon ions are attracted to the negatively charged target 102. The ions strike the target 102 at a substantial energy and cause target atoms or atomic clusters to be sputtered from the target 102. Some of the target particles strike the substrate 104 and are thereby deposited on it, thereby forming the film 105 of the target material. Alternately, the target material reacts with gas added to the argon to form a composite film including target material.

To provide efficient sputtering, opposing magnets 116 and 118 produce a magnetic field within the reactor 100 in the neighborhood of the magnets 116, 118. The magnetic field traps electrons and, for charge neutrality, the ion density also increases to form a high-density plasma region 120 within the reactor adjacent to the target 102.

Plasma ignition can present a significant problem, especially in the geometries representative of a commercially significant plasma reactor. The initial excitation of a plasma requires a high voltage, though with essentially no current, to cause the working gas to be excited into the electrons and positive ions of an electron. This condition must persist for a time period and over a space sufficient to support a low-resistance, essentially neutral plasma between the two electrodes in the case of a capacitively coupled plasma. The maintenance of a plasma requires a feedback condition in which argon atoms must supply as many electrons to the anode as ions to target. If the flow of electrons to the anode is insufficient, the plasma collapses or is never formed.

Pulsed DC sputtering, therefore, provides a method for the low temperature (less than 2000 degrees C.) deposition of oxide and silicon films. Low temperature processing is a critical when films are deposited on plastic substrates, such as the substrates used in the fabrication of flexible liquid crystal displays (LCDs).

With respect to the present invention, the target 102 is a single-crystal material with an embedded first impurity. The first impurity can be a transistion metal, such as Ni. Other first impurity materials are phosphorous or germanium. The film 105 is an amorphous silicon film with the first impurity of the target 102. The sputtering process deposits the first impurity as well as the silicon.

Although a pulsed DC sputtering tool 100 is shown in FIG. 1, equivalent results can be achieved using a standard, or non-pulsed DC-sputtering apparatus. The selection of the specific sputtering apparatus is dependent upon the resistivity of the Ni-doped Si target. For many applications, the pulsed-DC method is favored due to its better stability characteristics when sputtering relatively resistive materials (such as Si).

The Ni-doping level in the silicon target depends upon the Ni-doping requirement in the as-sputtered Si film. For effective silicide-assisted crystallization, a Ni concentration of 0.01 at % to 0.5 at % (atomic weight %) is required in the silicon film. This implies that this concentration range of Ni in the Si target should be in a similar range. However, there are differences in the sputtering yield between Ni and Si atoms. Ni has a 2-3 times higher yield than Si. Therefore, it may be concluded that a lower concentration range of Ni in the Si target yields the required concentration range in the sputtered film. The concentration range of Ni in the silicon target is then in the range of 0.05 at % to 0.2 at %.

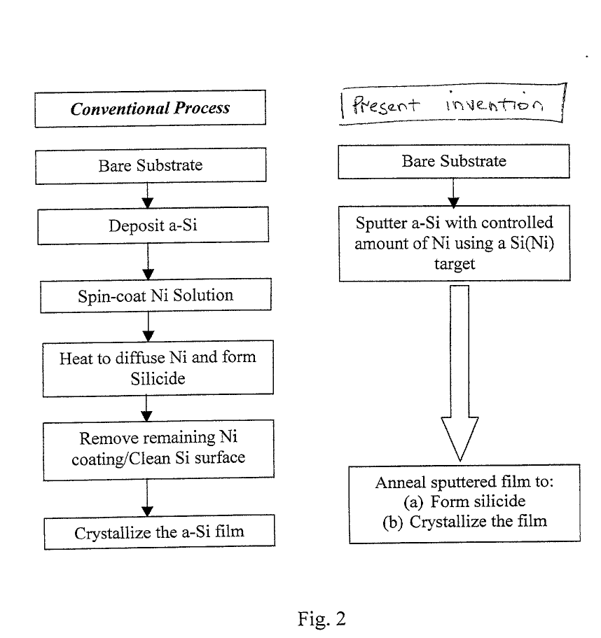

FIG. 2 is a comparison illustrating the number of steps saved in the present invention process of fabricating a silicon film with a controlled amount of impurities. Although there is not an exact correspondence between the steps of the present invention and conventional processes, it can be seen that the present invention process does not require the step and removing excess Ni. As noted in the Background Section above, the performance of this step in prior art processes often leads to damage in the silicon film that is detrimental to crystallization.

The silicon target can be doped with other materials besides transistion metals. For example, the Si target can be doped with germanium (Ge). Germanium enhances the crystallization of Si in subsequent annealing steps. The formation of a SiGe film yields better crystalline quality. It is easier to crystallize poly-Si films when the Ge concentration in the film is in the range of 5-30 at %. This implies similar concentration in the Si-Ge target material, since the yield for sputtering Ge is approximately the same as the yield for silicon.

Further, the Si target can be doped with P (phosphorous), in additional to doping the target with Ni or Ge. The P addition, permits the formation of lightly p-type poly-Si film. This light doping is beneficial for threshold voltage adjustment of thin film transistors (TFTs) fabricated from such poly-Si films. The level of P doping is determined based upon the magnitude of the Vth shift. Generally, the P concentration in the Si(Ni) or Si(Ge) target should be less than 5e17at/cm³, or less than 10 ppm.

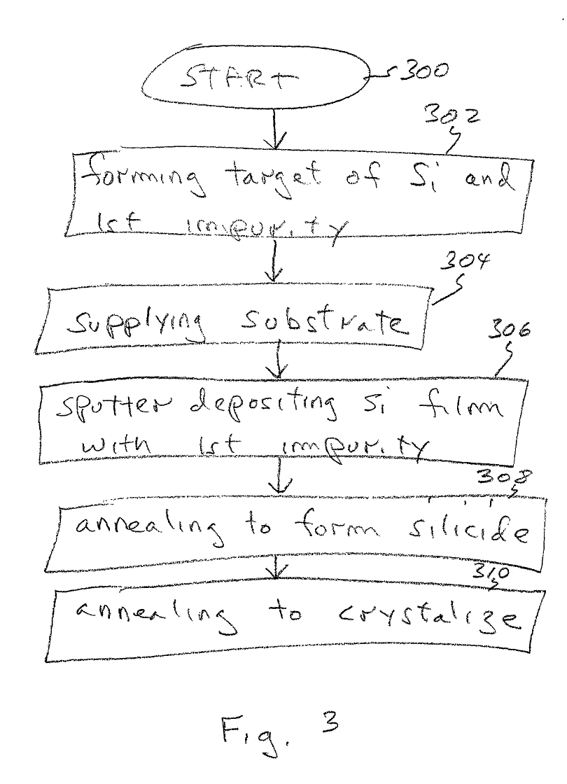

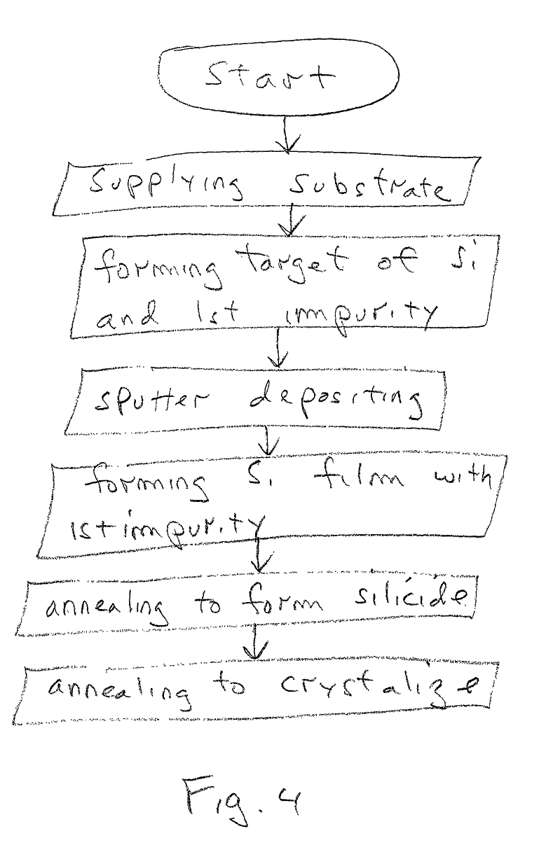

FIG. 3 is a flowchart illustrating the present invention method for forming silicon films with a controlled amount of trace impurities in the fabrication of LCDs. Although the method, and the method described by FIG. 4 below, is depicted as a sequence of numbered steps for clarity, no order should be inferred from the numbering unless explicitly stated. The method starts at Step 300. Step 302 forms a target including silicon and a first concentration of a first impurity. Typically, a single-crystal silicon target is formed. Step 304 supplies a substrate. Step 306 sputter deposits a film of silicon on the substrate including a second concentration of the first impurity. Typically, a film of amorphous silicon is formed. Sputter depositing a film of silicon on the substrate including a second concentration of the first impurity in Step 306 includes sputter depositing using a process selected from the group including pulsed and non-pulsed direct current (DC) sputtering.

Forming a target including silicon and a first concentration of a first impurity in Step 302 includes forming a target with a first impurity selected from the group including transistion metals, phosphorous, and germanium.

In some aspects of the invention, the first impurity is the transistion metal nickel. Then, forming a target including silicon and a first concentration of a first impurity in Step 302 includes forming a target with a first concentration of nickel in the range of 0.01 to 0.5 percentage by atomic weight (at %). Sputter depositing a film of silicon on the substrate including a second concentration of the first impurity in Step 306 includes depositing a silicon film including a second concentration of nickel in the range of 0.01 to 0.5 at %. However, because of the differences in yield between Si and Ni, Step 302 preferably forms a target with a first concentration of nickel in the range of 0.05 to 0.2 percentage by atomic weight (at %), while Step 306 deposits a silicon film including a second concentration of nickel in the range of 0.01 to 0.5 at %.

In some aspects of the invention, Step 302 forms a target including silicon, a first concentration of a nickel, and an additional third concentration of phosphorous less than 5×e¹⁷ atomic weight per cubic centimeter (at/cm³). Sputter depositing a film of silicon on the substrate including a second concentration of nickel in Step 306 includes depositing a silicon film with an additional fourth concentration of phosphorous sufficient to create a first Vth shift in the silicon film.

In some aspects, the method includes further steps. Step 308 anneals the silicon film including the first impurity of nickel to form a silicide. Step 310 anneals the silicon film with the nickel silicide to crystallize the silicon film.

Alternately, forming a target including silicon and a first concentration of a first impurity in Step 302 includes forming a target with a first concentration of germanium in the range of 5 to 30 at %. Sputter depositing a film of silicon on the substrate including a second concentration of the first impurity in Step 306 includes depositing a silicon film including a second concentration of germanium in the range of 5 to 30 at %.

In some aspects, Step 302 forms a target including silicon, a first concentration of a germanium, and an additional third concentration of phosphorous less than 5×e¹⁷ atomic weight per cubic centimeter (at/cm³). Sputter depositing a film of silicon on the substrate including a second concentration of germanium in Step 306 includes depositing a silicon film with an additional fourth concentration of phosphorous sufficient to create a first Vth shift in the silicon film.

FIG. 4 is a flowchart illustrating the present invention method for depositing silicon films with trace impurities in the fabrication of LCDs. The method starts at Step 400. Step 402 supplies a substrate. Step 404 forms a target of single-crystal silicon including a first concentration of the first impurity. Step 406 sputter deposits silicon and a controlled amount of a first impurity on the substrate. Sputter depositing silicon and a controlled amount of a first impurity on the substrate in Step 406 includes sputter depositing using a process selected from the group including pulsed and non-pulsed direct current (DC) sputtering. Step 408, following the sputter depositing, forms an amorphous silicon film including a second concentration of the first impurity overlying the substrate.

Forming a target of single-crystal silicon including a first concentration of the first impurity in Step 404 includes forming a target including a first impurity selected from the group including transistion metals, phosphorous, and germanium. The preferred transistion metal is nickel When Step 404 forms a target with a first concentration of nickel in the range of 0.01 to 0.5 percentage by atomic weight (at %), Step 408 forming an amorphous silicon film including a second concentration of nickel in the range of 0.01 to 0.5 at %. Preferably, the first concentration of Ni in the target is in the range of 0.05 to 0.2 percentage by atomic weight (at %).

In some aspects of the invention, forming a target of single-crystal silicon in Step 404 includes adding a first concentration of nickel with a third concentration of phosphorous less than 5×e¹⁷ atomic weight per cubic centimeter (at/cm³). Then, Step 408 forms a silicon film including a second concentration of nickel and a fourth concentration of phosphorous sufficient to create a first Vth shift in the silicon film. The definition of the first Vth shift is dependent upon the desired threshold adjustment of the final product TFT.

Step 410 anneals the silicon film including the nickel first impurity to form a nickel silicide. Step 412 anneals the silicon film with the nickel silicide to crystallize the silicon film.

When Step 404 forms a target of single-crystal silicon with a first concentration of germanium in the range of 5 to 30 at %, Step 408 forms an amorphous silicon film including a second concentration of germanium in the range of 5 to 30 at %. If Step 404 forms a target of single-crystal silicon including a first concentration of germanium and an additional third concentration of phosphorous less than 5×e¹⁷ atomic weight per cubic centimeter (at/cm³), Step 408 forms an amorphous silicon film including a second concentration of germanium and an additional fourth concentration of phosphorous sufficient to create a first Vth shift in the silicon film.

A method has been provided for controlling the amount of impurities deposited in a silicon film, for the purpose of enhancing the crystallization of the film. Specific examples of nickel and germanium dopants have been mentioned, however, the present invention is not limited to any particular doping material. The present invention process is especially relevant to LCD processes where low annealing temperatures are a concern. However, the process is applicable to IC fabrication in general. Other variations and embodiments of the invention will occur to those skilled in the art.

We Claim:

1. In the fabrication of liquid crystal displays (LCDs), a method for forming silicon films with a controlled amount of trace impurities, the method comprising:
forming a target including silicon and a first concentration of a first impurity;
supplying a substrate; and
sputter depositing a film of silicon on the substrate including a second concentration of the first impurity.

2. The method of claim 1 wherein forming a target including silicon and a first concentration of a first impurity includes forming a target with a first impurity selected from the group including transistion metals, phosphorous, and germanium.

3. The method of claim 2 wherein forming a target including silicon and a first concentration of a first impurity includes forming a target including a nickel first impurity.

4. The method of claim 3 wherein forming a target including silicon and a first concentration of a first impurity includes forming a target with a first concentration of nickel in the range of 0.01 to 0.5 percentage by atomic weight (at %); and,
wherein sputter depositing a film of silicon on the substrate including a second concentration of the first impurity includes depositing a silicon film including a second concentration of nickel in the range of 0.01 to 0.5 at %.

5. The method of claim 4 wherein forming a target including silicon and a first concentration of a first impurity includes forming a target with a first concentration of nickel in the range of 0.05 to 0.2 percentage by atomic weight (at %); and,
wherein sputter depositing a film of silicon on the substrate including a second concentration of the first impurity includes depositing a silicon film including a second concentration of nickel in the range of 0.01 to 0.5 at %.

6. The method of claim 4 wherein forming a target including silicon and a first concentration of a nickel includes forming the target with an additional third concentration of phosphorous less than 5×e¹⁷ atomic weight per cubic centimeter (at/cm³); and,
wherein sputter depositing a film of silicon on the substrate including a second concentration of nickel includes depositing a silicon film with an additional fourth concentration of phosphorous sufficient to create a first Vth shift in the silicon film.

7. The method of claim 1 wherein sputter depositing a film of silicon on the substrate including a second concentration of the first impurity includes sputter depositing using a process selected from the group including pulsed and non-pulsed direct current (DC) sputtering.

8. The method of claim 2 wherein forming a target including silicon and a first concentration of a first impurity includes forming a target with a first concentration of germanium in the range of 5 to 30 at %; and,
wherein sputter depositing a film of silicon on the substrate including a second concentration of the first impurity includes depositing a silicon film including a second concentration of germanium in the range of 5 to 30 at %.

9. The method of claim 8 wherein forming a target including silicon and a first concentration of a germanium includes forming the target with an additional third concentration of phosphorous less than 5×e¹⁷ atomic weight per cubic centimeter (at/cm³); and,
wherein sputter depositing a film of silicon on the substrate including a second concentration of germanium includes depositing a silicon film with an additional fourth concentration of phosphorous sufficient to create a first Vth shift in the silicon film.

10. The method of claim 3 further comprising:
annealing the silicon film including the first impurity of nickel to form a silicide; and,
annealing the silicon film with the nickel silicide to crystallize the silicon film.

11. The method of claim 1 wherein forming a target including silicon and a first concentration of a first impurity includes forming a target of single-crystal silicon; and,
wherein sputter depositing a film of silicon on the substrate including a second concentration of the first impurity includes forming a film of amorphous silicon.

12. In the fabrication of liquid crystal displays (LCDs), a method for depositing silicon films with trace impurities, the method comprising:
supplying a substrate; and
sputter depositing silicon and a controlled amount of a first impurity on the substrate.

13. The method of claim 12 further comprising:
forming a target of single-crystal silicon including a first concentration of the first impurity.

14. The method of claim 12 further comprising:
following the sputter depositing, forming an amorphous silicon film including a second concentration of the first impurity overlying the substrate.

15. The method of claim 13 wherein forming a target of single-crystal silicon including a first concentration of the first impurity includes forming a target with a first impurity selected from the group including transistion metals, phosphorous, and germanium.

16. The method of claim 15 wherein forming a target of single-crystal silicon including a first concentration of the first impurity includes forming a target including a nickel first impurity.

17. The method of claim 16 wherein forming a target of single-crystal silicon including a first concentration of the first impurity includes forming a target with a first concentration of nickel in the range of 0.01 to 0.5 percentage by atomic weight (at %); and,
wherein forming an amorphous silicon film including a second concentration of the first impurity includes forming a silicon film including a second concentration of nickel in the range of 0.01 to 0.5 at %.

18. The method of claim 17 wherein forming a target of single-crystal silicon including a first concentration of the first impurity includes forming a target with a first concentration of nickel in the range of 0.05 to 0.2 percentage by atomic weight (at %); and,
wherein forming an amorphous silicon film including a second concentration of the first impurity includes forming a silicon film including a second concentration of nickel in the range of 0.01 to 0.5 at %.

19. The method of claim 17 wherein forming a target of single-crystal silicon including a first concentration of nickel includes forming a target with an additional third concentration of phosphorous less than 5×e¹⁷ atomic weight per cubic centimeter (at/cm³); and,
wherein forming an amorphous silicon film including a second concentration of nickel includes forming a silicon film with an additional fourth concentration of phosphorous sufficient to create a first Vth shift in the silicon film.

20. The method of claim 12 wherein sputter depositing silicon and a controlled amount of a first impurity on the substrate includes sputter depositing using a process selected from the group including pulsed and non-pulsed direct current (DC) sputtering.

21. The method of claim 15 wherein forming a target of single-crystal silicon including a first concentration of the first impurity includes forming a target with a first concentration of germanium in the range of 5 to 30 at %; and,
wherein forming an amorphous silicon film including a second concentration of the first impurity includes forming a silicon film including a second concentration of germanium in the range of 5 to 30 at %.

22. The method of claim 21 wherein forming a target of single-crystal silicon including a first concentration of germanium includes forming a target with an additional third concentration of phosphorous less than 5×e¹⁷ atomic weight per cubic centimeter (at/cm³); and,
wherein forming an amorphous silicon film including a second concentration of germanium includes forming a silicon film with an additional fourth concentration of phosphorous sufficient to create a first Vth shift in the silicon film.

23. The method of claim 16 further comprising:
annealing the silicon film including the nickel first impurity to form a nickel silicide; and,
annealing the silicon film with the nickel silicide to crystallize the silicon film.
